(19) United States
(12) Patent Application Publication
(10) Pub. No.: US 2011/0165780 A1
(43) Pub. Date: Jul. 7, 2011

(54) METHODS OF FORMING RUTHENIUM-CONTAINING FILMS BY ATOMIC LAYER DEPOSITION

(75) Inventors: Ravi Kanjolia, North Andover, MA (US); Rajesh Odedra, Altrincham Cheshire (GB); Jeff Anthis, Harverhill, MA (US); Neil Boag, Mytholmroyd W. Yorkshire (GB)

(73) Assignee: Sigma-Aldrich Co., St. Louis, MO (US)

(21) Appl. No.: 12/992,268

(22) PCT Filed: May 29, 2009
(86) PCT No.: PCT/US2009/045677

§ 371 Date: Mar. 2, 2011

Related U.S. Application Data
(60) Provisional application No. 61/057,505, filed on May 30, 2008.

(51) Int. Cl. H01L 21/314

(52) U.S. Cl. 438/785; 257/E21.266

(57) ABSTRACT

A method of forming ruthenium-containing films by atomic layer deposition is provided. The method comprises delivering at least one precursor to a substrate, the at least one precursor corresponding in structure to Formula I: (L)Ru(CO)₃ wherein L is selected from the group consisting of a linear or branched C₂-C₆-alkenyl and a linear or branched C₁₋₆-alkyl; and wherein L is optionally substituted with one or more substituents independently selected from the group consisting of C₂-C₆-alkenyl, C₁₋₆-alkyl, alkoxy and NR¹R²; wherein R¹ and R² are independently alkyl or hydrogen.

### CROSS-REFERENCE TO RELATED APPLICATIONS

This patent claims the benefit of U.S. provisional application Ser. No. 61/057,505, filed on 30 May 2008, the disclosure of which is incorporated herein by reference in its entirety.

### FIELD OF THE INVENTION

The present invention relates to methods of forming ruthenium-containing films by atomic layer deposition (ALD), also known as atomic layer epitaxy.

### BACKGROUND OF THE INVENTION

ALD is a self-limiting, sequential unique film growth technique based on surface reactions that can provide atomic layer control and deposit conformal thin films of materials provided by, for example, titanium-based precursors onto substrates of varying compositions. In ALD, the precursors are separated during the reaction. The first precursor is passed over the substrate producing a monolayer on the substrate. Any excess unreacted precursor is pumped out of the reaction chamber. A second precursor is then passed over the substrate and reacts with the first precursor, forming a second monolayer of film over the first-formed layer on the substrate surface. This cycle is repeated to create a film of desired thickness. ALD processes have applications in nanotechnology and fabrication of semiconductor devices such as capacitor electrodes, gate electrodes, adhesive diffusion barriers and integrated circuits.

Chung, Sung-Hoon et al. report ruthenium films using tricarbonyl-1,3-cyclohexadienyl ruthenium by an ALD technique. “Electrical and Structural Properties of Ruthenium Film Grown by Atomic Layer Deposition using Liquid-Phase Ru(CO)₃(C₆H₈) Precursor.” Mater. Res. Soc. Symp. Proc. 2007. Volume 990.

Japanese Patent No. 2006-57112 to Tatsuy, S. et al. report using ruthenium precursors, such as (2,3 dimethyl-1,3-butadiene)tricarbonyl ruthenium, (1,3-butadiene)tricarbonyl ruthenium, (1,3-cyclohexadiene)tricarbonyl ruthenium, (1,4-cyclohexadiene)tricarbonyl ruthenium and (1,5-cyclooctadiene)tricarbonyl ruthenium, to form metal films by chemical vapor deposition.

U.S. Pat. No. 6,380,080 to Visokay, M. reports methods of preparing ruthenium metal films from liquid ruthenium complexes of the formula (diene)Ru(CO)₃ by chemical vapor deposition.

Current precursors for use in ALD do not provide the required performance to implement new processes for fabrication of next generation devices, such as semi-conductors. For example, improved thermal stability, higher volatility and increased deposition rates are needed.

### SUMMARY OF THE INVENTION

There is now provided a method of forming a ruthenium-containing film by atomic layer deposition. The method comprises delivering at least one precursor to a substrate, the at least one precursor corresponding in structure to Formula I:

(L)Ru(CO)₃ (Formula I)

wherein:
L is selected from the group consisting of a linear or branched C₂-C₆-alkenyl and a linear or branched C₁₋₆-alkyl; and wherein L is optionally substituted with one or more substituents independently selected from the group consisting of C₂-C₆-alkenyl, C₁₋₆-alkyl, alkoxy and NR¹R²; wherein R¹ and R² are independently alkyl or hydrogen.

Other embodiments, including particular aspects of the embodiments summarized above, will be evident from the detailed description that follows.

### BRIEF DESCRIPTION OF THE DRAWINGS

FIG. 1 is a graphical representation of thermogravimetric analysis (TGA) data demonstrating % weight loss vs. temperature of (1) (η⁴-buta-1,3-diene)tricarbonylruthenium, (2) (η⁴-2,3-dimethylbuta-1,3-diene)tricarbonylruthenium and (3) (cyclohexa-1,3-dienyl)Ru(CO)₃.

FIG. 2 is a picture of (cyclohexadienyl)tricarbonylruthenium (on left) and (η⁴-2,3-dimethylbuta-1,3-diene)tricarbonylruthenium (on right) following a thermal stability study.

### DETAILED DESCRIPTION

In various aspects of the invention, ALD methods are provided, utilizing ruthenium-based precursors to form either metal or metal oxide films. In a particular embodiment, a metal film is deposited.

### A. Definitions

As used herein, the term “precursor” refers to an organometallic molecule, complex and/or compound.

In one embodiment, the precursor may be dissolved in an appropriate hydrocarbon or amine solvent. Appropriate hydrocarbon solvents include, but are not limited to aliphatic hydrocarbons, such as hexane, heptane and nonane; aromatic hydrocarbons, such as toluene and xylene; aliphatic and cyclic ethers, such as diglyme, triglyme and tetraglyme. Examples of appropriate amine solvents include, without limitation, octylamine and N,N-dimethyldodecylamine. For example, the precursor may be dissolved in toluene to yield a 0.05 to 1M solution.

The term “alkyl” refers to a saturated hydrocarbon chain of 1 to about 6 carbon atoms in length, such as, but not limited to, methyl, ethyl, propyl and butyl. The alkyl group may be straight-chain or branched-chain. For example, as used herein, propyl encompasses both n-propyl and iso-propyl; butyl encompasses n-butyl, sec-butyl, iso-butyl and tert-butyl. Further, as used herein, “Me” refers to methyl, and “Et” refers to ethyl.

The term “alkenyl” refers to an unsaturated hydrocarbon chain of 2 to about 6 carbon atoms in length, containing one or more double bonds. Examples include, without limitation, ethenyl, propenyl, butenyl, pentenyl and hexenyl.

The term “dienyl” refers to a hydrocarbon group containing two double bonds. A dienyl group may be linear, branched, or cyclic. Further, there are unconjugated dienyl groups which have double bonds separated by two or more single bonds; conjugated dienyl groups which have double bonds separated by one single bond; and cumulated dienyl groups which have double bonds sharing a common atom.

The term “alkoxy” (alone or in combination with another term(s)) refers to a substituent, i.e., —O-alkyl. Examples of such a substituent include methoxy (—O—CH₃), ethoxy, etc. The alkyl portion may be straight-chain or branched-chain. For example, as used herein, propoxy encompasses both n-propoxy and iso-propoxy; butoxy encompasses n-butoxy, iso-butoxy, sec-butoxy, and tert-butoxy.

### B. Chemistry

In one embodiment, a method of forming a ruthenium-containing film by atomic layer deposition is provided. The method comprises delivering at least one precursor to a substrate, the at least one precursor corresponding in structure to Formula I:

(L)Ru(CO)₃ (Formula I)

wherein:
L is selected from the group consisting of a linear or branched C₂-C₆-alkenyl and a linear or branched C₁₋₆-alkyl; and wherein L is optionally substituted with one or more substituents independently selected from the group consisting of C₂-C₆-alkenyl, C₁₋₆-alkyl, alkoxy and NR¹R²; wherein R¹ and R² are independently alkyl or hydrogen.

In one embodiment, L is a linear or branched dienyl-containing moiety. Examples of such linear or branched dienyl-containing moieties include butadienyl, pentadienyl, hexadienyl, heptadienyl and octadienyl. In a further embodiment, the linear or branched dienyl-containing moiety is a 1,3-dienyl-containing moiety.

In another embodiment, L is substituted with one or more substituents such as C₂-C₆-alkenyl, alkoxy and NR¹R², where R¹ and R² are as defined above. In a particular embodiment, L is a dienyl-containing moiety and substituted with one or more substituents such as C₂-C₆-alkenyl, alkoxy and NR¹R², where R¹ and R² are as defined above.

In one embodiment, L may be substituted with one or more C₁₋₆-alkyl groups, such as, but not limited to, methyl, ethyl, propyl, butyl or any combination thereof.

Examples of the at least one precursor include, without limitation:
(η⁴-buta-1,3-diene)tricarbonylruthenium;
(η⁴-2,3-dimethylbuta-1,3-diene)tricarbonylruthenium; and
(η⁴-2-methylbuta-1,3-diene)tricarbonylruthenium.

Properties of two open dienyl compounds and a cyclohexadienyl compound are shown below:

| | | |
|---|---|---|
| 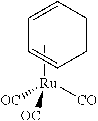 | 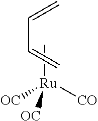 | 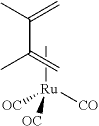 |
| η⁴-1,3-cyclohexadiene | η⁴-butadiene ruthenium | η⁴-2,3-dimethyl butadiene |
| ruthenium tricarbonyl | tricarbonyl | ruthenium tricarbonyl |
| (CHD)Ru(CO)₃ | (BD)Ru(CO)₃ | (DMBD)Ru(CO)₃ |
| Crystalline Solid | Yellow liquid | Yellow Liquid |
| at 20° C. | at 20° C. | at 20° C. |
| Boiling Point: 56° C. | (10 °C. MP) | (15° C. MP) |
| at 200 mtorr | Boiling Point: 28° C. | Boiling Point: 30° C. |
| Thermally stable | at 300 mtorr | at 300 mtorr |
| at 20° C. | Thermally stable | Thermally stable |
| | at 20° C. | at 20° C. |

### C. Oxygen and Non-Oxygen Co-Reactants

As stated above, the ALD process can be used to form either a thin metal or metal oxide film on substrates using at least one ruthenium precursor according to Formula I. The film can be formed by the at least one ruthenium precursor independently or in combination with a co-reactant (also known as a co-precursor).

Typically, ruthenium precursors require an oxidative environment (such as air, O₂, ozone or water) to deposit thin ruthenium films by ALD. Therefore, in one embodiment, a metal oxide film containing ruthenium is deposited onto a substrate. The at least one precursor may be delivered or deposited on a substrate in pulses alternating with pulses of an appropriate oxygen source, such as H₂O, H₂O₂, O₂, ozone or any combination thereof.

Further, it has been discovered that the ruthenium-containing precursors of the invention can deposit ruthenium-containing films using a non-oxygen co-reactant. Therefore, in another embodiment of invention the ruthenium-containing film is formed by atomic layer deposition using a non-oxygen co-reactant.

For example, the non-oxygen co-reactant may comprise substantially of a gaseous material such as hydrogen, hydrogen plasma, nitrogen, argon, ammonia, hydrazine, alkylhydrazine, silane, borane or any combination thereof. In a particular embodiment, the non-oxygen gaseous material is hydrogen.

### E. Substrates

A variety of substrates can be used in the methods of the present invention. For example, the precursors according to Formula I may be used to deposit ruthenium-containing films on substrates such as, but not limited to, silicon, silicon dioxide, silicon nitride, tantalum, tantalum nitride, or copper.

### F. Types of ALD

The ALD methods of the invention encompass various types of ALD processes. For example, in one embodiment conventional ALD is used to form a ruthenium-containing film. For conventional and/or pulsed injection ALD process see for example, George S. M., et. al. J. Phys. Chem. 1996. 100:13121-13131. Examples of conventional ALD growth conditions include, but are not limited to:

(1) Substrate temperature: 250° C.

(2) Ruthenium precursor temperature (source): 35° C.

(3) Reactor Pressure: 100 mtorr

(4) Pulse sequence (sec.) (precursor/purge/coreactant/purge): about 1/9/2/8

In another embodiment, liquid injection ALD is used to form a ruthenium-containing film, wherein a liquid precursor is delivered to the reaction chamber by direct liquid injection as opposed to vapor draw by a bubbler. For liquid injection ALD process see, for example, Potter R. J., et. al. Chem. Vap. Deposition. 2005. 11(3):159. Examples of liquid injection ALD growth conditions include, but are not limited to:

(1) Substrate temperature: 160-300° C. on Si(100)

(2) Evaporator temperature: about 100° C.

(3) Reactor pressure: about 1 ton

(4) Solvent: toluene

(5) Solution concentration: about 0.075 M

(6) Injection rate: about 50 μl pulse⁻¹

(7) Argon flow rate: about 10 cm³ min⁻¹

(8) Pulse sequence (sec.) (precursor/purge/coreactant/purge): about 2/8/2/8

(9) Number of cycles: 300

In another embodiment, photo-assisted ALD is used to form a ruthenium-containing film. For photo-assisted ALD processes see, for example, U.S. Pat. No. 4,581,249.

Thus, the organometallic precursors, according to Formula I, utilized in these methods may be liquid, solid, or gaseous. Particularly, the precursors are liquid at ambient temperatures with high vapor pressure for consistent transport of the vapor to the process chamber.

### G. Resistance

In another embodiment, the ruthenium-containing film is formed on a metal substrate and has a resistance of less than about 100 mohm/cm². In a particular embodiment, the metal substrate is tantalum or copper.

In another embodiment, the ruthenium-containing film is formed on a silicon or silicon dioxide substrate and the resistance is from about 20 ohm/cm² to about 100 mohm/cm².

Therefore, in a particular embodiment, the method of the invention is utilized for applications such as dynamic random access memory (DRAM) and complementary metal oxide semi-conductor (CMOS) for memory and logic applications on silicon chips.

### EXAMPLES

The following examples are merely illustrative, and do not limit this disclosure in any way.

### Example 1

### Precursor Properties

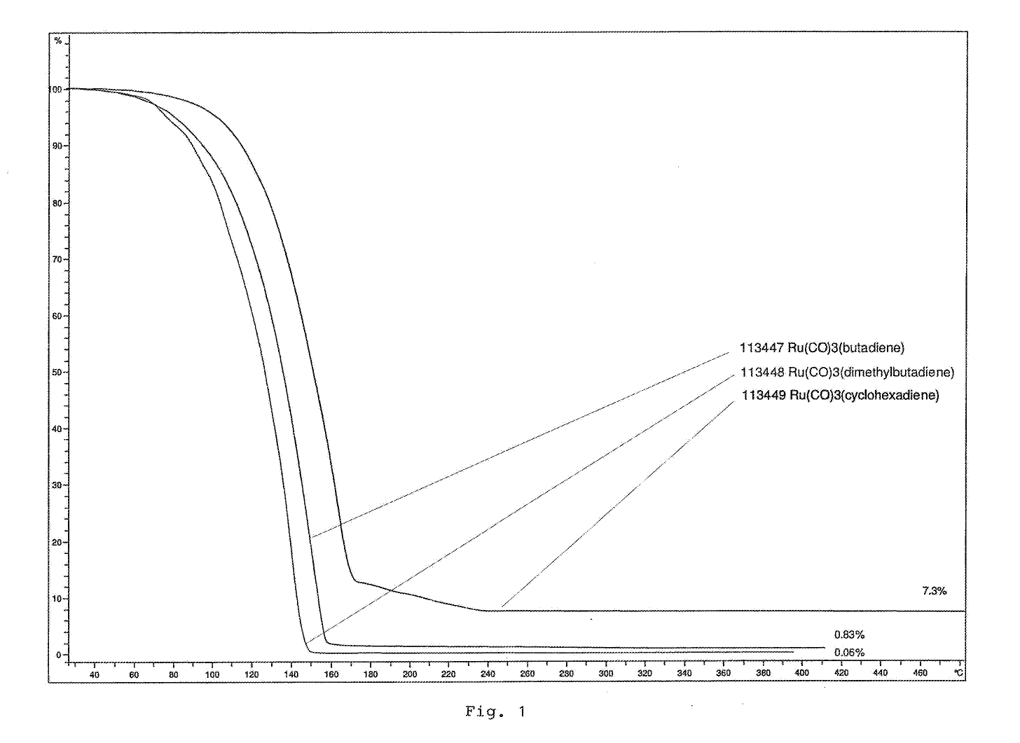

FIG. 1 compares TGA data of (η⁴-buta-1,3-diene)tricarbonylruthenium, (η⁴-2,3-dimethylbuta-1,3-diene)tricarbonylruthenium and (η⁴-1,3-cyclohexadienyl)-tricarbonylruthenium.

The result for (η⁴-buta-1,3-diene)tricarbonylruthenium was 0.83%.

The result for (η⁴-2,3-dimethylbuta-1,3-diene)tricarbonylruthenium was 0.06%.

The result for (η⁴-1,3-cyclohexadienyl)tricarbonylruthenium was 7.3%.

FIG. 1 illustrates that linear or branched (“open”) diene compounds are well suited to the ALD process because they are pure and vaporize congruently without decomposition. FIG. 1 demonstrates that the open dienes are more stable than the cyclohexadienyl derivative due to the lower residue indicated in the TGA which shows less degradation on thermal exposure. Typically good ALD sources (precursors) have TGA residues less than 5% and ideally less than 1%.

### Example 2

### Conventional ALD of (η⁴-buta-1,3-diene)tricarbonylruthenium

An ampoule containing (η⁴-buta-1,3-diene)tricarbonylruthenium was pre-heated in a hotbox to 35° C. A 2 cm² wafer coupon was loaded into the reaction chamber which was evacuated and heated to 250° C. The lines between the precursor oven and co-reactant gas (H₂) were heated to 45° C. Argon was purged into the chamber continuously at 10 sccm throughout the run. The run was started by pulsing in the precursor for 1 second followed by 9 seconds with only the Ar purge flowing. The co-reactant (H₂) was then pulsed for 2 seconds followed by 8 seconds with only the Ar purge flowing. This 1/9/2/8 sequence accounted for 1 cycle. The run was continued for 300 full cycles. After 300 cycles the precursor and co-reactant (H₂) were closed to the chamber and the system was allowed to cool to room temperature with a continued Ar purge of 10 sccm.

### Example 3

### Conventional ALD of (η⁴-2,3-dimethylbuta-1,3-diene)tricarbonylruthenium

An ampoule containing (η⁴-2,3-dimethylbuta-1,3-diene)tricarbonylruthenium was pre-heated in a hotbox to 35° C. A 2 cm² wafer coupon was loaded into the reaction chamber which was evacuated and heated to 250° C. The lines between the precursor oven and co-reactant gas (H₂) were heated to 45° C. Argon was purged into the chamber continuously at 10 sccm throughout the run. The run was started by pulsing in the precursor for 1 second followed by 9 seconds with only the Ar purge flowing. The co-reactant (H₂) was then pulsed for 2 seconds followed by 8 seconds with only the Ar purge flowing. This 1/9/2/8 sequence accounted for 1 cycle. The run was continued for 300 full cycles. After 300 cycles the precursor and co-reactant (H₂) were closed to the chamber and the system was allowed to cool to room temperature with a continued Ar purge of 10 sccm.

### Example 4

### Liquid injection ALD of (η⁴-2,3-dimethylbuta-1,3-diene)tricarbonylruthenium

An ampoule containing a solution of 1 g (η⁴-2,3-dimethylbuta-1,3-diene)tricarbonylruthenium in ca. 50 mL of toluene (0.075M) is pulsed into a vaporizer at 100° C. A 2 cm² wafer coupon is loaded into the reaction chamber which is evacuated and heated to 250° C. The lines between the reactor and the chamber are held at 110° C. and lines between the co-reactant gas (H₂) are heated to 45° C. Argon is purged into the chamber continuously at 10 sccm throughout the run. The run is started by pulsing in the evaporated precursor for 1 second followed by 9 seconds with only the Ar purge flowing. The co-reactant (H₂) is then pulsed for 2 seconds followed by 8 seconds with only the Ar purge flowing. This 1/9/2/8 sequence accounts for 1 cycle. The run is continued for 300 full cycles. After 300 cycles the precursor and co-reactant (H₂) are closed to the chamber and the system is allowed to cool to room temperature with a continued Ar purge of 10 sccm.

### Example 5

### Comparison of (η⁴-2,3-dimethylbuta-1,3-diene)tricarbonylruthenium, and (cyclohexadienyl)tricarbonylruthenium Thermal Stability

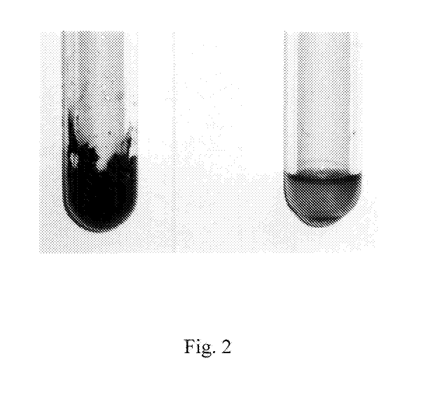

When (η⁴-1,3-cyclohexadienyl)tricarbonylruthenium and (η⁴-2,3-dimethylbuta-1,3-diene)tricarbonylruthenium were held at 110° C. for 13 hours under an inert atmosphere, the (η⁴-1,3-cyclohexadienyl)tricarbonylruthenium gradually decomposed while (η⁴-2,3-dimethylbuta-1,3-diene)tricarbonylruthenium remained unchanged. The results are depicted in FIG. 2. On left is (η⁴-1,3-cyclohexadienyl)tricarbonylruthenium and on right is (η⁴-2,3-dimethylbuta-1,3-diene)tricarbonylruthenium.

### Example 6

### Comparison of (BD)Ru(CO)3, (DMBD)Ru(CO)3, and (CHD)Ru(CO)3 Film Growth by ALD

Film growth by ALD using three different ruthenium precursors were compared using the following growth parameters:

| | | |
|---|---|---|
| 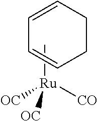 | 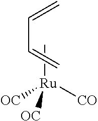 | 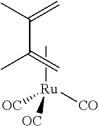 |
| η⁴-1,3-cyclohexadiene | η⁴-butadiene ruthenium | η⁴-2,3-dimethyl butadiene |
| ruthenium tricarbonyl | tricarbonyl | ruthenium tricarbonyl |
| (CHD)Ru(CO)₃ | (BD)Ru(CO)₃ | (DMBD)Ru(CO)₃ |
| Precursor Temp: 45° C. | Precursor Temp: 35° C. | Precursor Temp: 35° C. |
| Wafer Temp: 250 | Wafer Temp: 250 | Wafer Temp: 250 |
| 1s precursor/9s purge/ | 1s precursor/9s purge/ | 1s precursor/9s purge/ |
| 1s H2/9s purge | 1s H2/9s purge | 1s H2/9s purge |
| 100 mtorr | 100 mtorr | 100 mtorr |

The film properties were then compared and are shown below:

| | | |
|---|---|---|
| 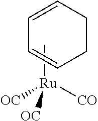 | 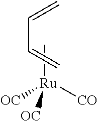 | 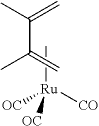 |
| η⁴-1,3-cyclohexadiene | η⁴-butadiene ruthenium | η⁴-2,3-dimethyl butadiene |
| ruthenium tricarbonyl | tricarbonyl | ruthenium tricarbonyl |
| (CHD)Ru(CO)₃ | (BD)Ru(CO)₃ | (DMBD)Ru(CO)₃ |
| Dep. Rate ≈ 240\acute{Å}/ | Dep. Rate ≈ 300\acute{Å}/ | Dep. Rate ≈ 300\acute{Å}/ |
| min @ 350 C. | min @ 350 C. | min @ 350 C. |
| Oxygen 2 E 20 | Oxygen 1 E 19 | O not measured |
| Resistivity 37 μΩ/sq | Resistivity 36 μΩ/sq | Resistivity 49 μΩ/sq |

It can now be seen that (BD)Ru(CO)₃, (DMBD)Ru(CO)₃ and (CHD)Ru(CO)₃ are all volatile Ru(0) precursors. Over extended periods, the open diene system is more stable than the closed diene system (such as the cyclohexadienyl precursor). Sheet resistance from all three substrates are between 36 and 49 μΩ/sq.

All patents and publications cited herein are incorporated by reference into this application in their entirety.

The words “comprise”, “comprises”, and “comprising” are to be interpreted inclusively rather than exclusively.

What is claimed is:

1. A method of forming a ruthenium-containing film by atomic layer deposition, the method comprising delivering at least one precursor to a substrate, the at least one precursor corresponding in structure to Formula I:
(L)Ru(CO)₃ (Formula I)
wherein:
L is selected from the group consisting of a linear or branched C₂-C₆-alkenyl and a linear or branched C₁₋₆-alkyl; and wherein L is optionally substituted with one or more substituents independently selected from the group consisting of C₂-C₆-alkenyl, C₁₋₆-alkyl, alkoxy and NR¹R²; wherein R¹ and R² are independently alkyl or hydrogen.

2. The method of claim 1, wherein L is a linear or branched dienyl-containing moiety.

3. The method of claim 1, wherein L is a linear or branched dienyl-containing moiety selected from the group consisting of butadienyl, pentadienyl, hexadienyl, heptadienyl and octadienyl.

4. The method of claim 1, wherein L is substituted with one or more substituents independently selected from the group consisting of C₂-C₆-alkenyl, C₁₋₆-alkyl, alkoxy and NR¹R²; and R¹ and R² are independently alkyl or hydrogen.

5. The method of claim 1, wherein the at least one precursor is selected from the group consisting of:
(η⁴-buta-1,3-diene)tricarbonylruthenium;
(η⁴-2,3-dimethylbuta-1,3-diene)tricarbonylruthenium; and
(η⁴-2-methylbuta-1,3-diene)tricarbonylruthenium.

6. The method of claim 1, wherein the atomic layer deposition is photo-assisted atomic layer deposition.

7. The method of claim 1, wherein the atomic layer deposition is liquid injection atomic layer deposition.

8. The method of claim 1, wherein the atomic layer deposition is pulsed injection atomic layer deposition.

9. The method of claim 1, wherein the ruthenium-containing film is formed by atomic layer deposition using a non-oxygen co-reactant.

10. The method of claim 9, wherein the non-oxygen co-reactant comprises substantially of a gaseous material selected from the group consisting of hydrogen, nitrogen, argon, ammonia, hydrazine, alkylhydrazine, silane and borane.

11. The method of claim 10, wherein the non-oxygen gaseous material is hydrogen.

12. The method of claim 1, wherein the substrate is selected from the group consisting of silicon, silicon oxide, silicon nitride, tantalum, tantalum nitride and copper.

13. The method of claim 1, wherein the substrate is metal and the resistance is less than about 100 mohm/cm².

14. The method of claim 13, wherein the substrate is tantalum or copper.

15. The method of claim 1, wherein the substrate is silicon or silicon dioxide and the resistance is from about 20 ohm/cm² to about 100 mohm/cm².

16. The method of claim 1, wherein the method is used for a memory and logic application on a silicon chip.

17. The method of claim 16, wherein the method is used for DRAM or CMOS applications.
